(19) United States
(12) Patent Application Publication
(10) Pub. No.: US 2009/0195248 A1
(43) Pub. Date: Aug. 6, 2009

(54) TABLE-TOP MAGNETIC RESONANCE IMAGING APPARATUS WITH PERMANENT MAGNET

(75) Inventors: SOU TIEN WANG, DANVILLE, CA (US); LAWRENCE E. CROOKS, RICHMOND, CA (US); ROBERT R. WAHRER, PLEASANTON, CA (US)

Correspondence Address: PATENTRY, P.O. BOX 151616, SAN RAFAEL, CA, 94915-1616, US

(73) Assignee: WANG NMR INC., LIVERMORE, CA (US)

(21) Appl. No.: 12/024,109

(22) Filed: Feb. 1, 2008

(51) Int. Cl. G01R 33/28

(52) U.S. Cl. 324/318

(57) ABSTRACT

A table-top MRI system with substantially reduced capital requirements enables various applications to be used on education and research institution and various laboratory use for MRI applications. A magnetic structure is disclosed with two rectangular permanent magnets, four right triangular permanent magnets, and four right trapezoidal permanent magnets. The MRI system further comprises an RF assembly distinguished by its tuning system.

### BACKGROUND

Nuclear Magnetic Resonance (NMR) Spectroscopy is a powerful, non-destructive analytical technique for elucidating the chemical composition and structure of matter. Magnet Resonance Imaging (MRI) employs similar techniques to render images of the inside of an object. The principles of nuclear magnetic resonance were first described and measured in molecular beams by Isidor Rabi in 1938. Eight years later, in 1946, Felix Bloch and Edward Mills Purcell refined the technique for use on liquids and solids, for which they shared the Nobel Prize in physics in 1952.

Conventional MRI instruments are very large and expensive. A problem fundamental to the multipurpose mission of conventional MRI is allowing a wide array of accessories which contribute to physical size and high capital cost. This is reflected in high installation cost and high maintenance cost. While electronics has been shown to be susceptible to miniturization by reducing voltages and dimensions, magnets generally suffer loss of field strength when they are made smaller and the problems of cooling superconductors acts to keep superconducting magnets from scaling down.

Thus it can be appreciated that what is needed is a substantial size reduction in magnets operated at room temperature and related reduction of all elements of an MRI system to benchtop size, specifically refined magnetic shims, and gradient coils, coupled to more efficient radio frequency circuits.

### SUMMARY OF THE INVENTION

An innovative laboratory MRI system is disclosed substantially lowering capital requirements for various applications to be used on education and research institution and various laboratory use for MRI applications.

The system consists of a permanent magnet having a north and a south pole, each aligned in north and south orientation. Each pole is accompanied with a pair of two side poles with magnetization polarity oriented to minimize the flux linkage and thus, maximize the central field while greatly improving the field uniformity. The magnetic structure design, as claimed is shown in FIG. 1A, FIG. 1B, FIG. 1C, and FIG. 1D. The magnetic field generated ranges from 0.3 T to 0.64 T within a single layer permanent magnet material.

A set of three axes actively shielded gradient coils generating a 5 G/cm gradient are designed and fabricated from double layer copper foil, as shown in FIG. 2A, 2B, and 2C. The primary gradient coil is equipped with an RF shield to reduce the interference between RF coil and gradient coil.

A RF assembly consists of an RF coil transmit and receive coil and its tuning circuit and a BALUN, a transmit/receive switch, a preamplifier, a noise gate, and a sample loader are shown in FIG. 3A, 3B, and 3C.

### BRIEF DESCRIPTION OF DRAWINGS

FIG. 1A is a cross sectional view of a table-top mri.

FIG. 1B is an exterior side view of a table-top mri.

FIG. 1C is an exterior front view of a table-top mri.

FIG. 1D is an exterior rear view of a table-top mri.

FIG. 2A is a front view of the interior of a table-top mri.

FIG. 2B is a side view of the interior of a table-top mri.

FIG. 2C is a perspective view of interior of a table-top mri.

FIG. 3A is a schematic diagram of an RF circuit of a table-top mri with tuning relay.

FIG. 3B is a schematic diagram of an RF circuit of a table-top mri with tuning loop.

FIG. 3C is a schematic diagram of an RF circuit of a table-top mri with tuning stub.

### DETAILED DESCRIPTION

The present invention is an apparatus for nuclear magnetic resonance imaging the invention includes the following improved apparatus: radio frequency transmitting and receiving circuits, magnetic shims, and a magnetic structure made up of permanent magnets in three solid shapes. These include
a plurality of rectangular prisms;
a plurality of right trapezoidal prisms, and
a plurality of right triangular prisms, enclosing a cavity.

The permanent magnet blocks shaped as prisms include at least two right triangular prisms fabricated with magnetic orientation orthogonal to the largest surface and with north oriented towards the 90 degree corner of the triangle and at least two right triangular prisms are permanent magnets fabricated with magnetic orientation oriented bisecting the 90 degree corner of the triangle and north oriented toward the largest surface.

Two rectangular prisms are permanent magnets fabricated with magnetic orientation orthogonal to the largest surface and a first rectangular prism attaching two right triangular prisms to present a magnetic lens focusing a north pole inward toward a cavity and a second rectangular prism attaching two right triangular prisms to present a magnetic lens disbursing a north pole outward away from a cavity.

A first pair of right trapezoidal prisms are permanent magnets fabricated with magnetic orientation orthogonal to the larger of two parallel surfaces with north oriented towards the smaller of two parallel surfaces the right trapezoidal prisms attaching to the right triangular prisms with north pole at the 90 degree corner and a second pair of right trapezoidal prisms are permanent magnets fabricated with magnetic orientation orthogonal to the smaller of two parallel surfaces with north oriented toward the larger of two parallel surfaces, the second pair of right triangular prisms attaching to the right triangular prisms with north pole at the largest surface wherein an acute angle of each right trapezoidal prism is attached to an acute angle of a second right trapezoidal prism.

To provide a uniform field within the cavity, a first shim plate attaches to a first rectangular prism and to a first pair of right triangular prisms and a second shim plate attaches to a second rectangular prism and to a second pair of right triangular prisms. A second pair of shim plates provides quadrupole field uniformity around the specimen for magnetic resonance imaging.

The magnetic structure has an exterior yoke of high permeability material entirely encapsulating the outer surface of the prisms. In an embodiment high permeability steel is used for field confinement.

The apparatus further comprises three pairs of actively shielded gradient coils (x, y, z), each actively shielded gradient coil comprised of double layer copper foil.

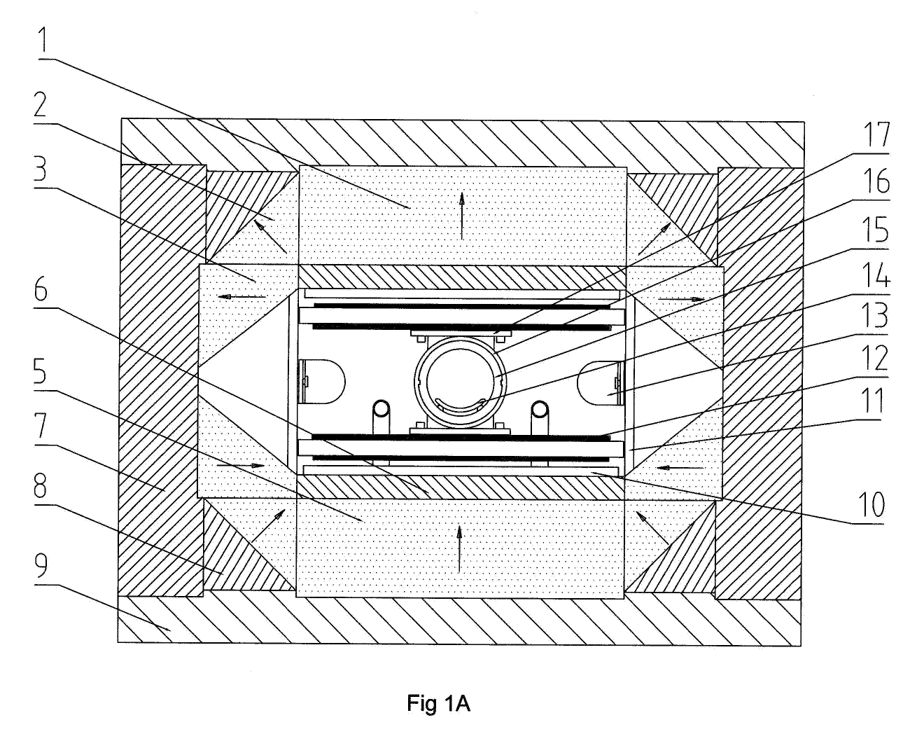

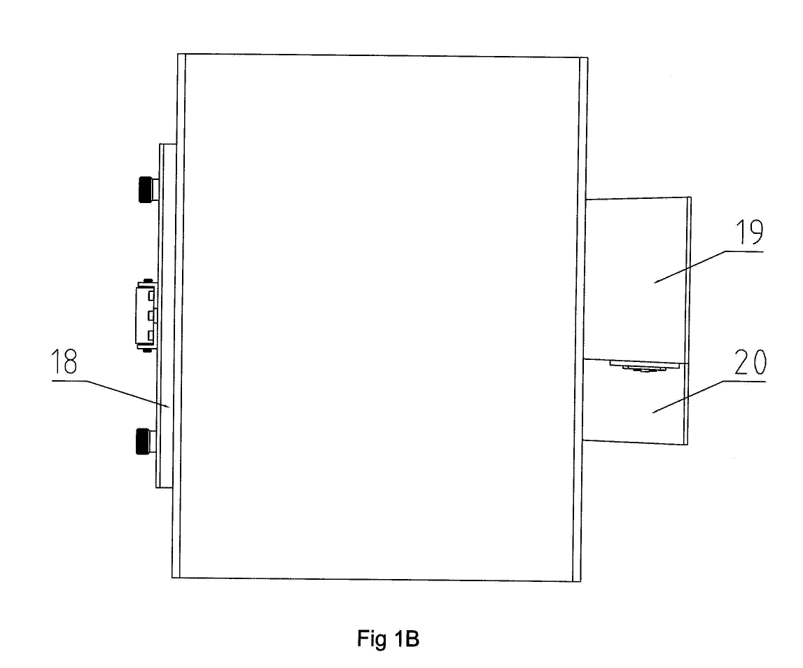

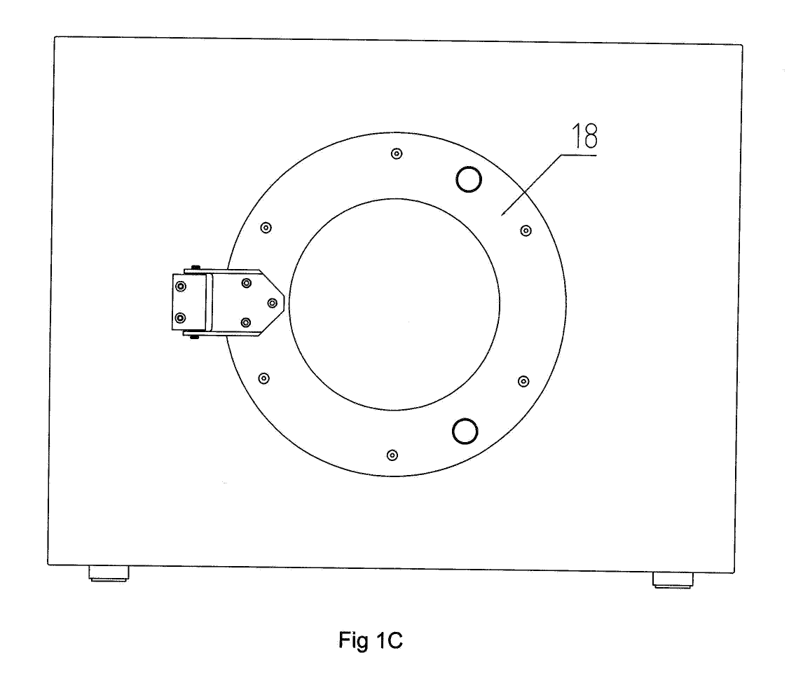

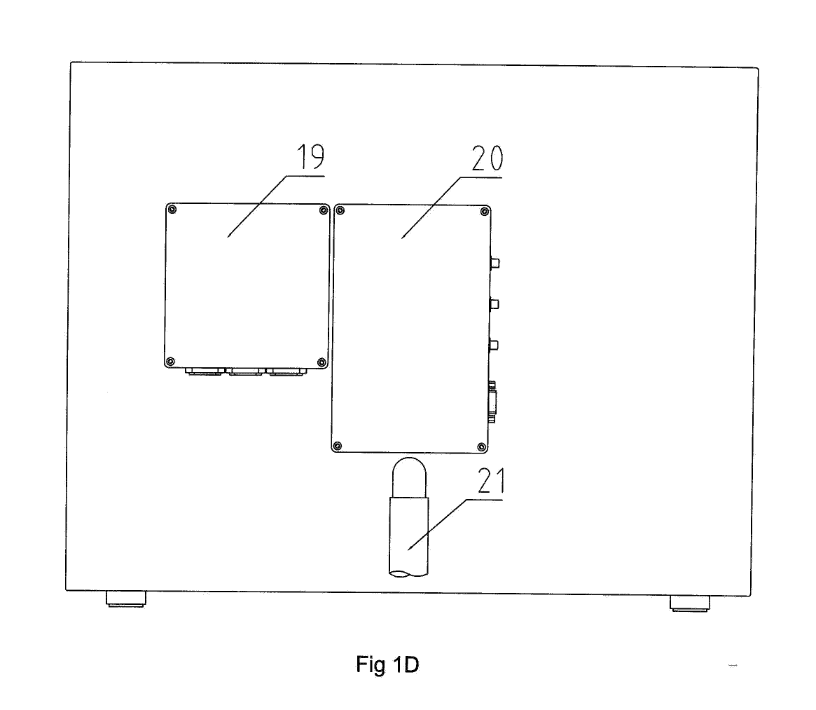

Referring now to the drawing FIG. 1A, the apparatus comprises a first rectangular prism 1 attached to two right triangular prisms 2, each right triangular prism attaching a right trapezoidal prism 3 with north magnetic poles oriented outward from the concave surface defined by the prisms. The apparatus further comprises a second rectangular prism 5 attached to two right triangular prisms each right triangular prism attached to a right trapezoidal prism with north magnetic poles oriented inward toward the concave surface defined by the second set of prisms. Two high purity ferrous pole pieces 6 are placed within the cavity defined by the magnetic prisms. The magnetic prisms are enclosed by ferrous materials such as iron or steel 7,8, and 9 to provide support and a magnetic yoke for flux return. The apparatus further comprises top and bottom shim plates 10 and side shim plates 11 to compensate for non-uniformity of the field generated by the prisms. Gradient coils 12 provide pulsed gradient fields to enable detailed sensing of nuclear magnetic resonance.

In an embodiment, the enclosure is illuminated by at least one row of light emitting diode lamps 13. In an embodiment, an assembly supports and encloses a sample comprising a base mount for a sample tube 17, an RF coil 16, a sliding tube for the sample 15, and sample support and holder 14.

Referring now to FIG. 1B, an exterior side view, an embodiment of the invention has a front door 18, a gradient coil filter enclosure 19, and an RF assembly enclosure 20. Referring now to FIG. 1C, an exterior front view, an embodiment of the invention has a front door 18. Referring now to FIG. 1D, an exterior rear view, an embodiment of the invention has a gradient coil filter enclosure 19, an RF assembly enclosure 20, and a temperature stability air duct 21.

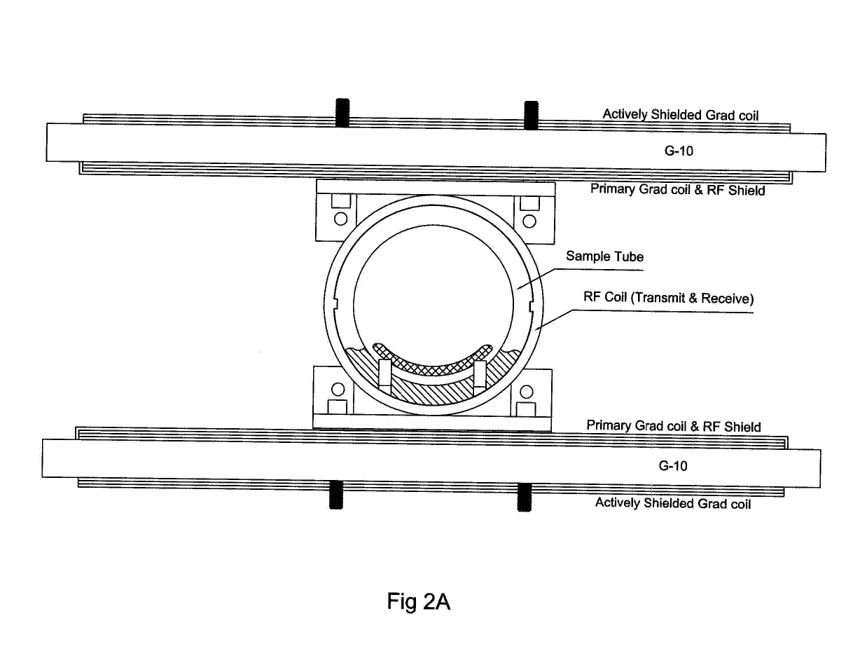

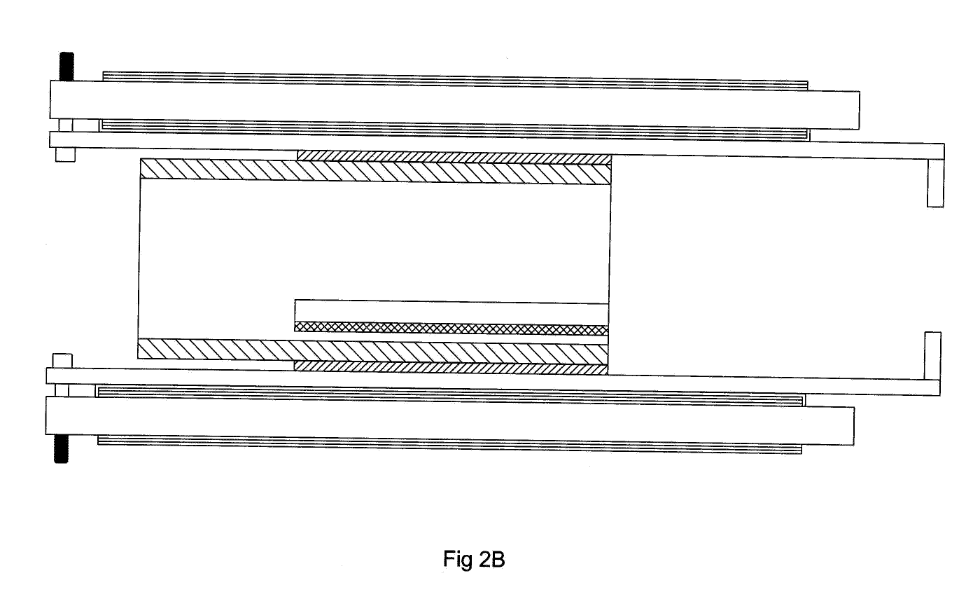

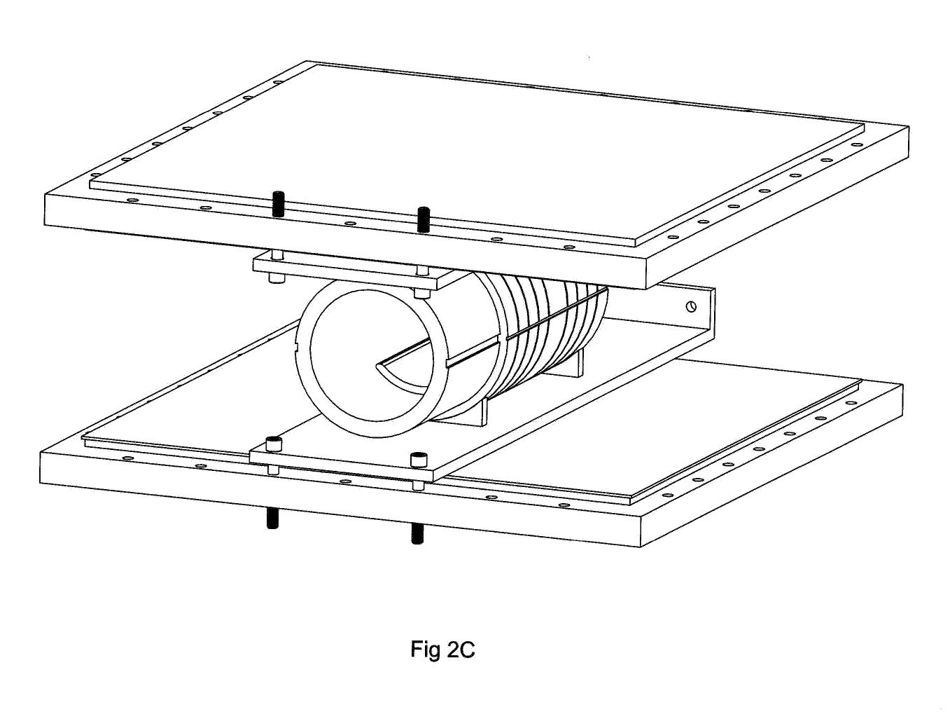

Referring now to FIG. 2A, a front elevation view shows further details of a sample tube, an RF coil( transmit & receive), a sliding tube for the sample and the sample support and holder suspended between a first primary gradient coil & RF shield and a second primary gradient coil and RF shield. In the embodiment illustrated, the primary gradient coils are structurally supported via a non-active member G-10. In the embodiment illustrated, the invention further comprises a pair of actively shielded gradient coils attaching to the outer surface of the non-active member G-10. Referring now to FIG. 2B, a side elevation view shows the side of the sliding tube for the sample and the sample support and holder suspended between gradient coils. Referring now to FIG. 2C, a perspective view shows the sliding tube for the sample and the sample support and holder, and RF coil suspended between the gradient coils.

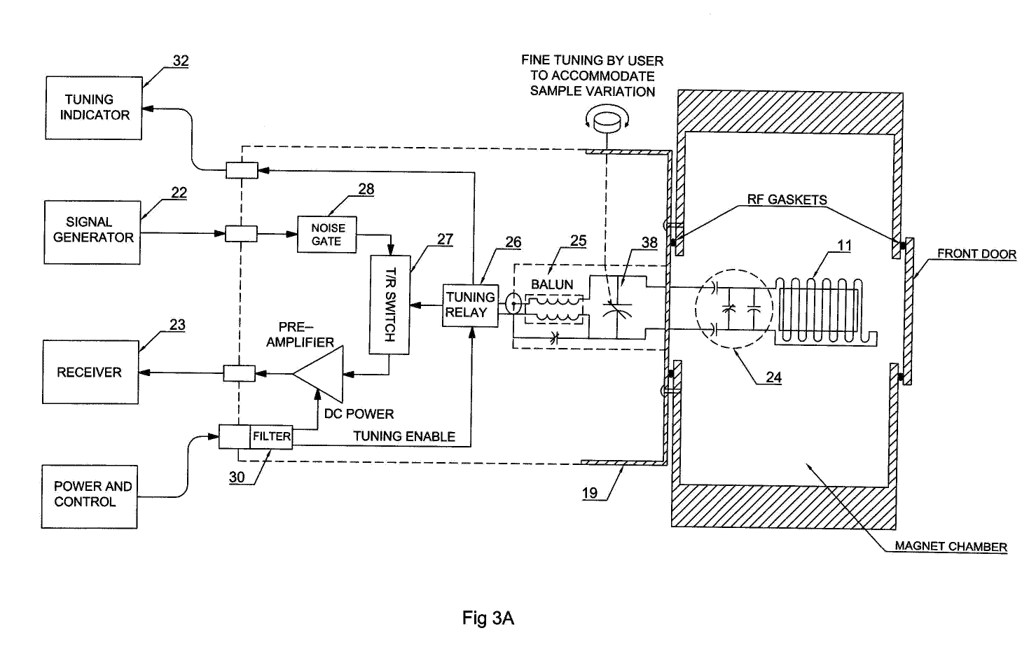

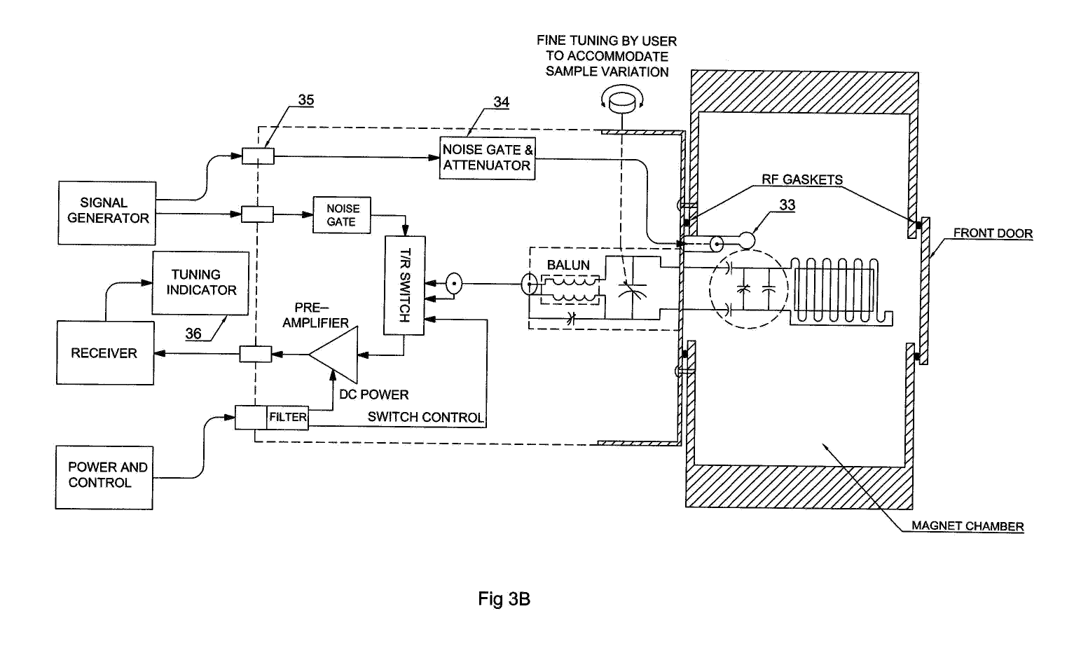

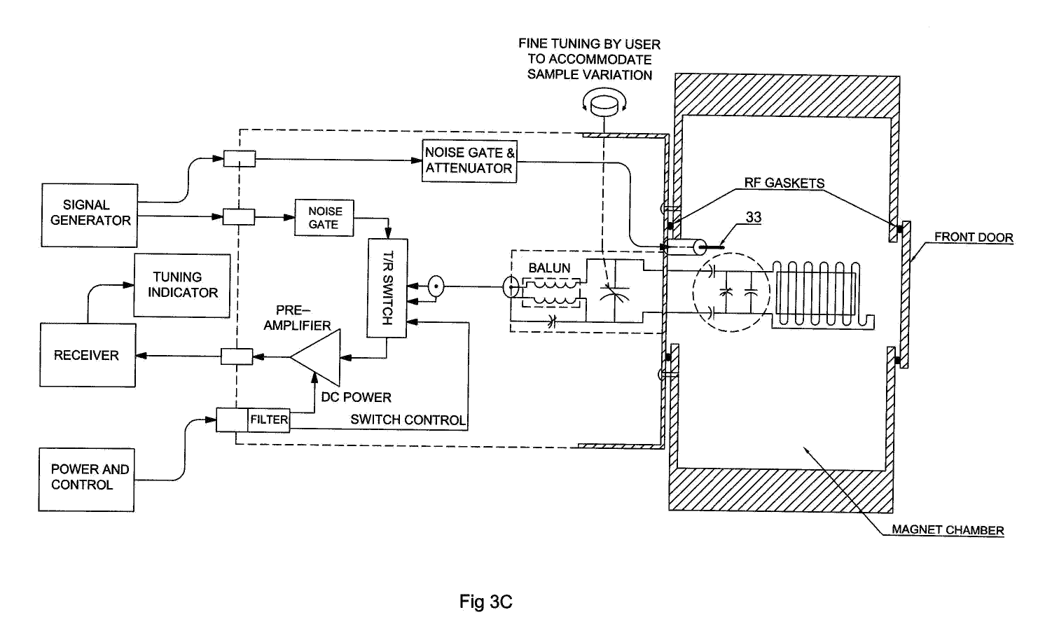

Referring now to FIG. 3A, the apparatus comprises a radio frequency (RF) circuit with tuning controls. The radio frequency (RF) circuit comprises a radio frequency assembly 19 containing a signal generator 22 and receiver 23.

The radio frequency (RF) assembly 19 for a laboratory magnet resonance imaging system, comprises a transmit and receive coil 11, coupled to a coil tuning network 24 and fine tuning capacitor 38, the tuning network coupled to a BALUN 25, and the BALUN coupled to a tuning relay 26.

The radio frequency assembly further comprises an active transmit receive switch 27 coupled to the tuning relay and further coupled to a noise gate 28 and to a preamplifier, with the preamplifier coupled to a DC power filter 30 and to the output of the RF assembly. The degree of tuning is indicated by an external tuning indicator 32.

Referring now to FIG. 3B, an embodiment of the invention has a transmit/receive switch coupled to the BALUN and further coupled to a noise gate and to a preamplifier. The radio frequency assembly further comprises a tuning loop 33 to introduce a small signal into the transmit/receive coil and further coupled to an attenuator 34 and noise gate assembly further coupled to an external port 35 whereby a tuning signal is introduced for calibration. The degree of tuning is indicated by a tuning indicator 36 operating in conduction with the receiver.

Referring now to FIG. 3C, an embodiment of the invention comprises a tuning stub 33 to introduce a signal into the transmit/receive coil and further coupled to an attenuator and noise gate assembly further coupled to an external port whereby a tuning signal is introduced for calibration.

The radio frequency assembly further comprises an external receiver 23 coupled to the preamplifier and further coupled to a tuning indicator whereby the degree of fine tuning is visualized.

The radio frequency assembly also includes the noise gate coupled to a transmit input power supply external to the assembly, the tuning relay coupled to a tuning unit external to the assembly, and a tuning control input, and the tuning network further comprising coarse tuning adjustments and fine tuning adjustments. The course tuning controls are variable capacitors set at the factory and the fine tuning control 38 is a variable capacitor with user accessible vernier. The present invention is distinguished from conventional nmr imaging systems by not having a separate band-pass filter because the novel coil tuning network operates in conjunction with the preamplifier's input matching circuit. The present invention is distinguished from conventional nmr imaging systems by using an active transmit receive switch configuration controlled by a logic level signal. The RF assembly is distinguished from conventional nmr imaging RF assemblies by the physically small unit size which is less than 2% of the wavelength at the operating frequency which removes the need for precise impedance matching among the components of the RF assembly. The complete RF assembly is distinguished from conventional RF assemblies by being easily removable in the field and be replaced with a unit which has been customized for a particular application while requiring only fine tuning adjustment after installation.

A simple magnetic structure for generating a uniform magnetic field capable of implementing NMR imaging of objects within a cavity is disclosed in the present patent application, the magnetic structure comprising: a) an elongated annular body having a longitudinal axis and comprising a plurality of substantially uniformly magnetized prisms of permanent magnet material forming by its interior surfaces a cavity, the annular body having a cross-section in the X-Y plane of a Cartesian coordinate system, the cavity being closed on the top, bottom, left side, and right side except for the ends for introducing and removing objects and transmitting and receiving radio frequency signals, b) a pair of rectangular prisms, two pair of right triangular prisms, and two pair of right trapezoidal prism, fabricated in permanent magnet material, the prisms being longitudinally aligned along the longitudinal axis and orthogonal to the X-Y plane, the intensity of the magnetic field being oriented along the Y-axis by the orientation of the magnetic poles in aggregate prisms, c) the orientation of the magnetic field in the cavity being normal to the inner surface of the rectangular prisms, and d) an exterior yoke of high permeability material.

The prism shaped permanent magnetic blocks are constituted of rare earth alloys magnetized to operate within a linear range of their demagnetization characteristics.

### Conclusion

The present invention is easily distinguished from conventional magnetic structures and NMR imaging apparatus by assembly of only 5 pairs of permanent magnet blocks which are formed in only three solid prism shapes: rectangular, right triangular, and right trapezoidal. The gradient coils and shims are distinguished by greater refinement over conventional gradient coils and shims. The present invention is further distinguished by a second pair of shim plates arranged on the sides of the chamber orthogonal to the field of the magnet.

The various features of novelty which characterize the invention are pointed out with particularity in the claims annexed to and forming a part of this disclosure. Those skilled in the art will appreciate that the invention is not necessarily limited to structures with the dimensions indicated in the drawings, which are only to illustrate the size of a particular embodiment. The preferred geometry illustrated can be replaced by other geometries following the principles disclosed herein. These other geometries are also considered within the scope of the invention. While the invention has been described in connection with preferred embodiments, it will be understood that modifications thereof within the principles outlined above will be evident to those skilled in the art and thus the invention is not limited to the preferred embodiments but is intended to encompass such modifications.

The scope of the invention includes all modification, design variations, combinations, and equivalents that would be apparent to persons skilled in the art, and the preceding description of the invention and its preferred embodiments is not to be construed as exclusive of such.

Reference throughout this specification to “one embodiment”, “an embodiment”, or “a specific embodiment” means that a particular feature, structure, or characteristic described in connection with the embodiment is included in at least one embodiment of the present invention and not necessarily in all embodiments. Thus, respective appearances of the phrases “in one embodiment”, “in an embodiment”, or “in a specific embodiment” in various places throughout this specification are not necessarily referring to the same embodiment. Furthermore, the particular features, structures, or characteristics of any specific embodiment of the present invention may be combined in any suitable manner with one or more other embodiments. It is to be understood that other variations and modifications of the embodiments of the present invention described and illustrated herein are possible in light of the teachings herein and are to be considered as part of the spirit and scope of the present invention.

It will also be appreciated that one or more of the elements depicted in the drawings/figures can also be implemented in a more separated or integrated manner, or even removed or rendered as inoperable in certain cases, as is useful in accordance with a particular application.

As used in the description herein and throughout the claims that follow, “a”, “an”, and “the” includes plural references unless the context clearly dictates otherwise. Also, as used in the description herein and throughout the claims that follow, the meaning of “in” includes “in” and “on” unless the context clearly dictates otherwise.

The foregoing description of illustrated embodiments of the present invention, including what is described in the Abstract, is not intended to be exhaustive or to limit the invention to the precise forms disclosed herein. While specific embodiments of, and examples for, the invention are described herein for illustrative purposes only, various equivalent modifications are possible within the spirit and scope of the present invention, as those skilled in the relevant art will recognize and appreciate. As indicated, these modifications may be made to the present invention in light of the foregoing description of illustrated embodiments of the present invention and are to be included within the spirit and scope of the present invention.

Thus, while the present invention has been described herein with reference to particular embodiments thereof, a latitude of modification, various changes and substitutions are intended in the foregoing disclosures, and it will be appreciated that in some instances some features of embodiments of the invention will be employed without a corresponding use of other features without departing from the scope and spirit of the invention as set forth. Therefore, many modifications may be made to adapt a particular situation or material to the essential scope and spirit of the present invention.

What is claimed is:

1. An apparatus for magnetic resonance comprising
at least two rectangular prisms;
at least four right trapezoidal prisms, and
at least four right triangular prisms, enclosing a cavity.

2. The apparatus of claim 1 wherein at least two right triangular prisms are permanent magnets fabricated with magnetic orientation orthogonal to the largest surface and with north oriented towards the 90 degree corner of the triangle and at least two right triangular prisms are permanent magnets fabricated with magnetic orientation oriented bisecting the 90 degree corner of the triangle and north orient toward the largest surface.

3. The apparatus of claim 1 wherein at least two rectangular prisms are permanent magnets fabricated with magnetic orientation orthogonal to the largest surface and a first rectangular prism attaching two right triangular prisms to present a magnetic lens focusing a north pole inward toward a cavity and a second rectangular prism attaching two right triangular prisms to present a magnetic lens disbursing a north pole outward away from a cavity.

4. The apparatus of claim 2 wherein a first pair of right trapezoidal prisms are permanent magnets fabricated with magnetic orientation orthogonal to the larger of two parallel surfaces with north oriented towards the smaller of two parallel surfaces the right trapezoidal prisms attaching to the right triangular prisms with north pole at the 90 degree corner and a second pair of right trapezoidal prisms are permanent magnets fabricated with magnetic orientation orthogonal to the smaller of two parallel surfaces with north oriented toward the larger of two parallel surfaces, the second pair of right triangular prisms attaching to the right triangular prisms with northpole at the largest surface wherein an acute angle of each right trapezoidal prism is attached to an acute angle of a second right trapezoidal prism.

5. The apparatus of claim 1 further comprising a first shim plate attaching to a first rectangular prism and to a first pair of right triangular prisms and a second shim plate attaching to a second rectangular prism and to a second pair of right triangular prisms and further comprising a third and fourth shim plate arranged orthogonally to the first and second shim plates.

6. The apparatus of claim 1 further comprising an exterior yoke of high permeability material entirely encapsulating the outer surface of the prisms.

7. The apparatus of claim 1 further comprising three actively shielded gradient coils comprised of double layer copper foil.

8. The apparatus of claim 1 further comprising a radio frequency signal generator and receiver.

9. A magnetic structure for generating a uniform magnetic field capable of implementing NMR imaging of objects within a cavity, the magnetic structure comprising: a) an elongated annular body having a longitudinal axis and comprising a plurality of substantially uniformly magnetized prisms of permanent magnet material forming by its interior surfaces a cavity, the annular body having a cross-section in the X-Y plane of a Cartesian coordinate system, the cavity being closed on the top, bottom, left side, and right side except for the ends for introducing and removing objects and transmitting and receiving radio frequency signals, b) a pair of rectangular prisms, two pair of right triangular prisms, and two pair of right trapezoidal prism, fabricated in permanent magnet material, the prisms being longitudinally aligned along the longitudinal axis and orthogonal to the X-Y plane, the intensity of the magnetic field being oriented along the Y-axis by the orientation of the magnetic poles in aggregate prisms, d) the orientation of the magnetic field in the cavity being normal to the inner surface of the rectangular prisms, and e) an exterior yoke of high permeability material.

10. The magnetic structure of claim 9 wherein the prism shaped permanent magnetic blocks are constituted of rare earth alloys magnetized to operate within a linear range of their demagnetization characteristics.

11. A radio frequency (RF) assembly for a laboratory magnet resonance imaging system, comprising a transmit and receive coil, coupled to a tuning network, the tuning network coupled to a BALUN.

12. The radio frequency assembly of claim 11 further comprising a tuning relay coupled to the BALUN and further coupled to a transmit/receive and further coupled to a noise gate and to a preamplifier.

13. The radio frequency assembly of claim 12 further comprising the noise gate coupled to a transmit input power supply external to the assembly, the tuning relay coupled to a tuning unit external to the assembly, and a tuning control input, and the tuning network further comprising coarse tuning adjustments and fine tuning adjustments.

14. The radio frequency assembly of claim 11 further comprising an active transmit/receive switch coupled to the BALUN and further coupled to a noise gate and to a preamplifier.

15. The radio frequency assembly of claim 14 further comprising a tuning loop coupled to an attenuator and noise gate assembly further coupled to an external port whereby a tuning signal is introduced for calibration.

16. The radio frequency assembly of claim 14 further comprising a tuning stub coupled to an attenuator and noise gate assembly further coupled to an external port whereby a tuning signal is introduced for calibration.

17. The radio frequency assembly of claim 14 further comprising an external receiver coupled to the preamplifier and further coupled to a display whereby the degree of fine tuning is visualized.
